(19) United States
(12) Patent Application Publication
(10) Pub. No.: US 2024/0429901 A1
(43) Pub. Date: Dec. 26, 2024

(54) ULTRA-LOW CLOCK POWER MULTI-BIT FLIP-FLOPS USING UNIDIRECTIONAL DEVICES

(71) Applicant: Intel Corporation, Santa Clara, CA (US)

(72) Inventors: Steven K. Hsu, Lake Oswego, OR (US); Amit Agarwal, Hillsboro, OR (US); Abhishek Anil Sharma, Portland, OR (US); Ram K. Krishnamurthy, Portland, OR (US)

(21) Appl. No.: 18/340,679

(22) Filed: Jun. 23, 2023

(51) Int. Cl. H03K 3/037; H03K 17/687

(52) U.S. Cl. CPC H03K 3/037; H03K 17/6872

(57) ABSTRACT

Embodiments herein relate to a multi-bit flip-flop circuit which uses unidirectional transistors to allow sharing of transistors among a set of flip-flops, while avoiding charge sharing within or between the flip-flops. Clock devices in the circuit can be shared to reduce the clock transistor gate capacitance and associated power consumption. The shared transistors can provide keeper circuits and/or tri-state inverters in a primary latch and a secondary latch in each flip-flop. One example implementation uses tri-state keeper sharing. Another example implementation uses tri-state keeper and/or pass gate sharing. Another example implementation uses pass gate sharing and no keeper.

### FIELD

The present application generally relates to the field of flip-flops and, more particularly, to reducing power consumption in a multi-bit flip-clop circuit.

### BACKGROUND

Flip-flop circuits, also referred to as flip-flops, are basic components of sequential logic circuits in computing devices. A flip-flop can include one or more latches which each store a bit of data in a storage node, where the value of the bit is represented by one of two stable states. A flip-flop also receives a clock signal which indicates when data is to be latched and output. However, reducing the power consumed by flip-flops is a continuing challenge.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1A depicts an example multi-bit flip-flop circuit 100 which uses bidirectional field-effect transistors (FETs), in accordance with various embodiments.

FIG. 1B depicts an example implementation of the flip-flop 150 of FIG. 1A, in accordance with various embodiments.

FIG. 2A depicts an example configuration of bidirectional FETs where no charging sharing occurs, in accordance with various embodiments.

FIG. 2B depicts an example configuration of bidirectional FETs where charging sharing occurs, in accordance with various embodiments.

FIG. 2C depicts an example configuration of unidirectional FETs where no charging sharing occurs, in accordance with various embodiments.

FIG. 3 depicts an example multi-bit flip-flop circuit 300 which uses unidirectional FETs, with tri-state keeper sharing, in accordance with various embodiments.

FIG. 4A depicts an example implementation of the flip-flop 350 of FIG. 3, with tri-state keeper sharing, in accordance with various embodiments.

FIG. 4B depicts an example first subset of shared keeper devices consistent with FIG. 4A, in accordance with various embodiments.

FIG. 4C depicts an example second subset of shared keeper devices consistent with FIG. 4A, in accordance with various embodiments.

FIG. 5 depicts an example multi-bit flip-flop circuit 500 which uses unidirectional FETs, with tri-state keeper and/or pass gate sharing, in accordance with various embodiments.

FIG. 6 depicts an example implementation of the flip-flop 550 of FIG. 5, with tri-state keeper and pass gate sharing, in accordance with various embodiments.

FIG. 7 depicts an example configuration of a first tri-state inverter (TSI1) and a second tri-state inverter (TSI2) of the flip-flop 550 of FIG. 6, in accordance with various embodiments.

FIG. 8 depicts flip flop 850 as another example implementation of the flip flop 550 of FIG. 5, with pass gate sharing and no keeper, in accordance with various embodiments.

FIG. 9 illustrates an example of components that may be present in a computing system 950 for implementing the techniques (e.g., operations, processes, methods, and methodologies) described herein.

### DETAILED DESCRIPTION

As mentioned at the outset, various challenges are presented in reducing the power consumed by flip-flops in in computing devices.

Flip-flops are ubiquitous in many types of computing devices including a power-constrained server/mobile microprocessor, a discrete or integrated graphics processor, and an artificial intelligence (AI)/machine-learning accelerator. These processors/accelerators may be arranged, e.g., in a System in Package (SiP), System on a Chip (SoC), or a stacked tile/chiplet design which includes multiple integrated circuits/chips within the same package. In these and other devices, clocking is one of the most significant power contributors and limiters.

Reducing power in computing systems with tight power budgets improves performance by allowing integration of more processor cores, memory and other processing elements, and improves battery life for mobile and edge network devices.

In particular, dynamic clocking power is the largest contributor and consumes up to 60% of the overall chip power dissipation, where most of the load is in the final flip-flops. A flip-flop is the fundamental circuit used in all digital synchronous systems and must be very low power since it contributes the most to the clocking power. Typically, flip-flops utilize minimum sized devices and cannot be further downsized to reduce power. Moreover, with process technology scaling, circuits are limited by variations to enable low-voltage operation for high energy-efficiency. This limits the smallest allowable device size, preventing any further dynamic power savings though transistor sizing. Since performance, power, and area (PPA) benefits are slowing down as process technology scales to smaller dimensions, there is a need for circuit innovations to improve PPA, specifically to reduce clocking power. Also, with a strong demand for higher frequency central processing units (CPUs), graphic processors and AI accelerators, deeper pipelines will only exacerbate the problem of clocking power consumption.

One potential solution to reduce power and improve power efficiency is to lower the supply voltage. However, this reduces performance due to degradation in the transistor on current (Ion). Simultaneous scaling of supply voltage and transistor threshold voltage (Vth) may recuperate the Ion reduction due to lower supply voltage. However, the use of such low Vth transistors significantly increases the leakage power component of total power.

Another possible solution involves Ultra-Low-Temperature (ULT) operation, e.g., 0 C, −100 C or lower. ULT operation is of interest in various fields such as cryogenic computing, quantum computing, and space exploration, where low temperatures can offer significant advantages. ULT operation provides the advantage of increased mobility and steeper sub-threshold slope, resulting in enhanced transistor Ion/Ioff ratio. Moreover, combining ULT with low Vth transistors at ultra-low-voltage (ULV), e.g., sub threshold voltages, results in a processor-voltage-temperature (PVT) corner, which can achieve the same or higher performance while significantly reducing dynamic/leakage power. However, ULT requires extremely low voltage operation/low-power design to keep the cooling cost overhead at a manageable level. Hence, it is desirable to develop circuits/architectures that enable low supply voltage operation (Vmin), low power, and high performance at such low temperatures.

Design opportunities for ULT/ULV include emerging applications such as quantum computing and cryptocurrency-mining application-specific integrated circuits (ASICs), e.g., for Bitcoin. Quantum computing operates at cryogenic temperatures, which creates new circuit design opportunities utilizing design-technology co-optimization due to the reduction in leakage. Furthermore, cryptocurrency-mining accelerators operate at extremely low voltages and use keeperless circuits to reduce area and power beyond conventional approaches.

Furthermore, emerging devices for post-Si and beyond complementary metal-oxide semiconductor (CMOS) can exhibit unidirectional (asymmetric) behavior, where current can essentially only flow in one direction through a transistor. Such asymmetric devices include negative differential resistance MOSFETs, gated Gunn devices, asymmetrical III-V metal-oxide-semiconductor field-effect transistors (MOSFETs) and tunnel field-effect transistors (TFETs). A unidirectional/asymmetric transistor generally allows current to flow in only one direction.

Negative differential resistance (NDR) is a phenomenon where the current decreases with increasing voltage. It is often associated with devices such as Gunn devices or tunnel diodes. It is also possible to achieve a negative differential resistance behavior in MOSFETs by exploiting certain device structures or operating conditions. One example is the resonant-tunneling transistor (RTT), also known as the Esaki transistor. This is a specialized MOSFET designed to exhibit NDR characteristics. The RTT operates based on quantum mechanical tunneling through thin barriers within the transistor structure. By controlling the bias conditions and geometry of the device, it is possible to achieve NDR in the current-voltage characteristics of the RTT.

A gated Gunn device or transistor, also known as a Gunn diode transistor or transferred electron device (TED), is a type of semiconductor device that exhibits the NDR characteristic. The device is based on the Gunn effect, which is the phenomenon of electron transit-time oscillations in certain semiconductor materials. The Gunn effect occurs when a high electric field is applied to a specific type of material, such as gallium arsenide (GaAs), indium phosphide (InP), or gallium nitride (GaN).

Asymmetrical III-V MOSFETs, also known as asymmetric heterojunction transistors, are a type of MOSFET that utilize III-V compound semiconductors in their device structure. These transistors combine different III-V semiconductor materials with silicon or silicon dioxide to create heterojunctions, enabling enhanced performance compared to traditional silicon MOSFETs. In an asymmetrical III-V MOSFET, the channel region is formed using a III-V semiconductor material such as gallium arsenide (GaAs), indium phosphide (InP), or other compound semiconductors.

A TFET is a type of transistor that operates based on quantum tunneling principles. It is an alternative to traditional MOSFETs and offers potential advantages such as lower power consumption and better control of sub-threshold leakage current. In a TFET, the current flow is achieved through band-to-band tunneling, which allows electrons to tunnel through a thin barrier from the source to the channel region of the transistor. This tunneling mechanism enables TFETs to operate at lower voltages and exhibit steeper sub-threshold characteristics compared to conventional MOSFETs. TFETs typically employ materials with a narrow bandgap, such as III-V compound semiconductors or two-dimensional materials like graphene or transition metal dichalcogenides. The narrow bandgap facilitates efficient quantum tunneling.

From a circuit design standpoint, further optimizations can be made with unidirectional FETS, which cannot be performed with conventional bidirectional FETs, improving clock power in a flip-flop. Also, due to these optimizations critical transistors in key circuits can achieve an “effective” 1DG or Z1 device size through sharing, lowering clock power and random variation effects. 1DG or Z1 refer to the minimum size transistor width the process allows.

Moreover, multi-bit flip-flops can be used to reduce clock power by enabling sharing of local clock inverters to reduce clock power. However, there are diminishing returns using multi-bit flip-flops. For example, after combining eight or more flip-flops, there is not much additional power/area savings achievable.

The solutions provided herein address the above and other issues. In one aspect, the solutions utilize unidirectional/asymmetrical FETs for device sharing in a multi-bit flip-flop circuit to reduce power. Critical clock devices in the circuit can be shared to significantly reduce the clock transistor gate capacitance. Tests have demonstrated a reduction of over 40%, for example.

The solutions can reduce clock power to meet stringent power budgets of computing devices. Reducing clock power improves the power benefit beyond what the process and conventional standard cell libraries provide. A standard-cell library is a collection of low-level electronic logic functions such as AND, OR, INVERT, flip-flops, latches, and buffers. Additionally, the solutions are compatible with the best known low-power multi-bit flip-flop strategies employed in today's standard cell libraries.

In one example implementation, the solutions provides a multi-bit flip-flop circuit which uses unidirectional FETs and tri-state keeper sharing.

In another example implementation, the solutions provides a multi-bit flip-flop circuit which uses unidirectional FETs and tri-state keeper and/or pass gate sharing.

In another example implementation, the solutions provides a multi-bit flip-flop circuit which uses unidirectional with pass gate sharing and no keeper.

These and other features will be further apparent in view of the following discussion.

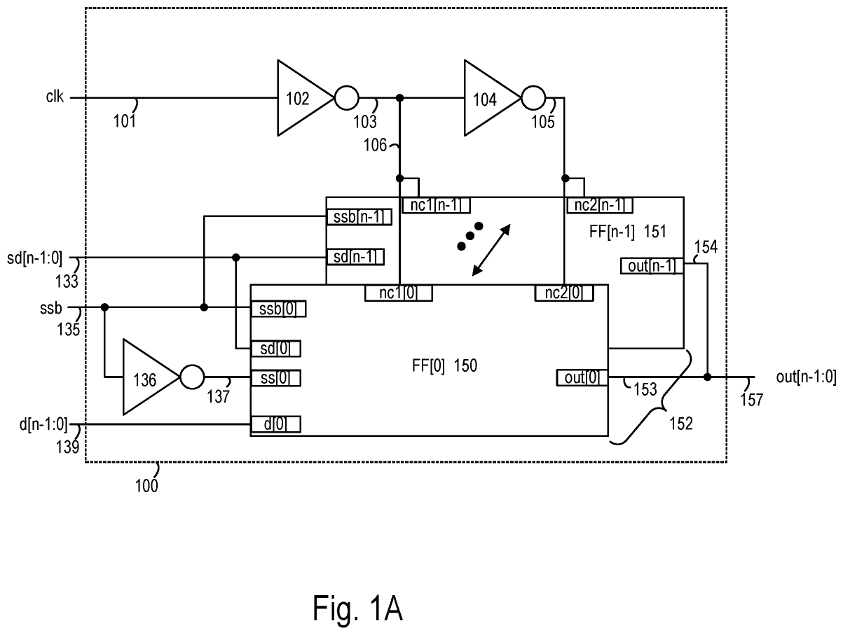

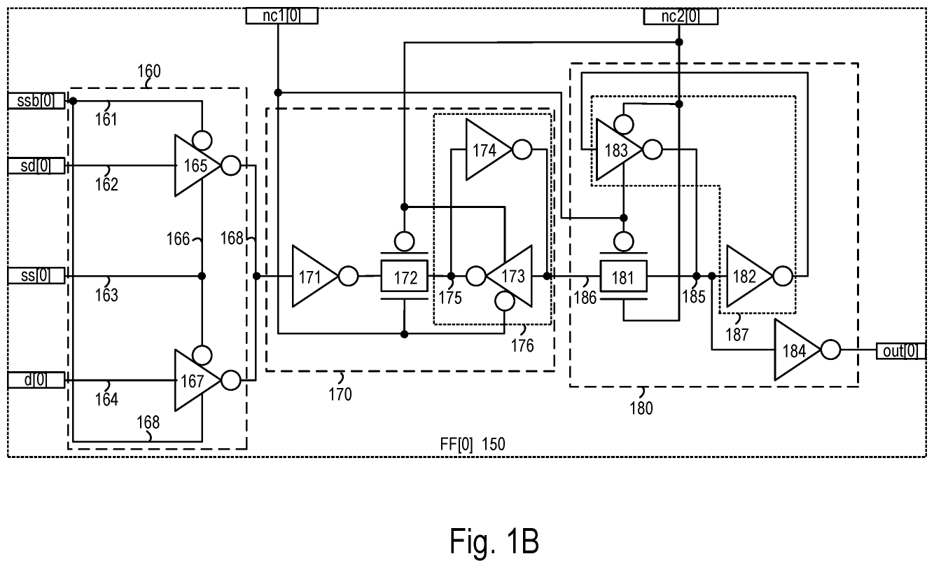

FIG. 1A depicts an example multi-bit flip-flop circuit 100 which uses bidirectional field-effect transistors (FETs), in accordance with various embodiments. The circuit receives a number of shared or common inputs including a clock signal (clk) on a path 101, a scan data signal sd[n−1:0] on a path 133, a scan select signal ssb on a path 135 and a data signal d[n−1:0] on a path 139. The circuit further includes a number n>1 of flip-flips FF[0] 150, . . . , FF[n−1] 151 in a set of flip-flops 152. Each flip-flop (or flip-flop circuit) receives the shared inputs at respective input terminals. For example, input terminals nc1[0], . . . , nc1[n−1] receive clk after it is inverted at an inverter 102 and provided on paths 103 and 106. Input terminals nc2[0], . . . , nc2[n−1] receive the signal on the path 103 after it is inverted at an inverter 104 and provided on a path 105. Input terminals ssb[0], . . . ssb[n−1] receive ssb. Input terminals sd[0], . . . sd[n−1] receive a respective bit from the set of n bits denoted by sd[n−1:0]. Input terminals ss[0], . . . ss[n−1] receive a signal ss, which is the complement or inverse of ssb, after ssb is inverted at an inverter 136 and output on a path 137. Input terminals d[0], . . . d[n−1] receive a respective bit from the set of n data bits denoted by d[n−1:0]. Note that the d and ss input terminals are depicted here for FF[0] only for clarity. Each flip-flop may have the same input and output terminals, in one approach.

Each flip-flop includes internal components which are controlled by the input signals to provide an output at a respective output terminal out[0], . . . , out[n−1] on paths 153, . . . , 154. The bits on the paths 153, . . . , 154 are combined at a path 157 to provide the final output out[n−1:0].

The inverters 102 and 104 are clock devices in this example, e.g., devices which receive a clock signal.

FIG. 1B depicts an example implementation of the flip-flop 150 of FIG. 1A, in accordance with various embodiments. The flip-flop may be D-type primary-secondary flip-flop, in one example implementation. This type of flip-flop includes a primary latch 170 in series with a secondary latch 180, which receives a data bit from the primary latch and provides it as an output under the control of a clock signal.

The flip-flop includes a multiplexer 160 which passes sd[0] on path 162 or d[0] on path 164 to a node 168. The multiplexer includes tri-state inverters 165 and 167. A tri-state invertor, also referred to as a tri-state buffer, can include an active high input connected to a first signal, e.g., ss[0], via paths 163 and 166 and an active low input connected to the complement of the first signal, e.g., ssb[0] via path 161. If the signals denote an enable state, the tri-state inverter passes and inverts an input bit to the output. When not enabled, the tri-state inverter has a high impedance state at its output and does not pass the input bit. In a data latching mode of the flip-flop, the tri-state inverter 167 inverts and passes d[0] to the node 168.

The primary latch 170 inverts the data input at an inverter 171 and passes it to a storage node 175 when a transmission gate 172, also referred to as a pass gate, is enabled. The pass gate has a non-inverting input coupled to the clock signal at the input terminal nc1[0] and an inverting input coupled to the clock signal at the input terminal nc2[0]. The transmission gate 172 is enabled when the voltage at nc2 [0] is low and the voltage at nc1[0] is high. The primary latch includes a keeper circuit 176 (or circuit, generally) which includes a tri-state inverter 173 and an inverter 174. The keeper circuit helps maintain the data bit at the storage node 175, e.g., in a low or high state. The data bit is inverted at the inverter 174 and the output of the inverter is input to the tri-state inverter 173. Based on the clock signal from nc2[0] at its non-inverting input and the clock signal from nc1[0] at its inverting input, the tri-state inverter 173 passes its input to its output at the storage node 175 to reinforce the voltage level of the stored data bit.

Additionally, the data bit is output from the primary latch to the secondary latch at a path 186. The data bit is passed by the transmission gate 181, when enabled, to a storage node 185, where its value is maintained by a keeper circuit 187 which include an inverter 182 and a tri-state inverter 183. The transmission gate 181 is enabled when the voltage at nc1[0] is low and the voltage at nc2[0] is high. The data at the storage node 185 can be output via an inverter 184 to the output terminal out[0].

The transmission gates 172 and 181 and the tri-state inverters 173 and 183 are clock devices in this example.

Note that in this and other diagrams, conductive paths which cross are generally not connected at the crossing point unless a black circle is shown at the crossing point to denote a connection.

The flip-flop 150 has the disadvantage that a full keeper circuit is provided within the flip-flop. The solutions described below overcome this disadvantage.

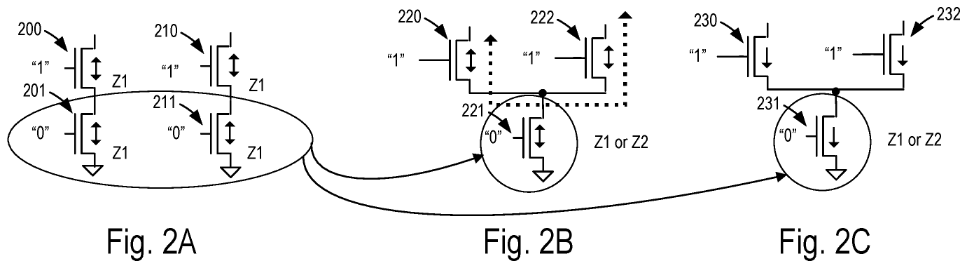

FIG. 2A depicts an example configuration of bidirectional FETs where no charging sharing occurs, in accordance with various embodiments. Series-connected FETs 200 and 201 receive 1 and 0 data bits, respectively, at their control gates while series-connected FETs 210 and 211 also receive 1 and 0 data bits, respectively, at their control gates. A 1 bit denotes a high voltage which turns on (makes conductive) an n-type FET, in this example. A 0 bit denotes a low (0 V) voltage which turns off (makes non-conductive) an n-type FET. The bidirectional arrows indicate that the FETs are bidirectional. Z1 denotes an impedance of the transistors. No charge sharing occurs between the FETs 200 and 210 since they are not coupled to one another.

FIG. 2B depicts an example configuration of bidirectional FETs where charging sharing occurs, in accordance with various embodiments. In this example, FETs 220 and 222 are connected in parallel with each other and in series with a FET 221. The FETs 220 and 222 are turned on by the 1 bit at their control gates while the FET 221 is turned off by the 0 bit at its control gate. The dotted arrow indicates a charge sharing path in which current can flow. The impedance of the FET 221 is Z1 or Z2. Accordingly, the bidirectional FETs result in a condition where charge sharing can occur between two FETs. This prohibits many circuit topologies since it can corrupt state nodes.

FIG. 2C depicts an example configuration of unidirectional FETs where no charging sharing occurs, in accordance with various embodiments. With the use of unidirectional or asymmetric FETs, current can only flow in one direction, enabling new circuit topologies with sharing of devices (e.g., transistors) for reduced capacitance and power consumption. Furthermore, device sharing enables the use of large width transistors which have a high tolerance to device variations. In this case, the FETs 230 and 232 are connected in parallel with each other and in series with a FET 231. The FETs 230 and 232 are turned on by the 1 bit at their control gates while the FET 231 is turned off by the 0 bit at its control gate. The impedance of the FET 221 is Z1 or Z2. The downward pointing arrows indicate a current flow direction, which is from a power supply at the top of the circuit to ground.

The circled regions indicate how two turned off FETs in FIG. 2A are replaced by a single turned off FET.

Further to the earlier discussion regarding various types of unidirectional devices, examples of ways of making unidirectional devices can generally involve modifying the source and drain terminals of a transistor differently. A first technique of modification involves differential doping. This results in a difference in the number of carriers, e.g., boron, phosphorus, arsenic, etc. in the source vs, the drain. The range of the difference is can be >2x. That is, the doping concertation of one terminal can be 2× that of the other terminal. A typical concentration of carriers is ˜1e20 to 1e21 carriers/cm3. Differential doping helps increase the carriers injected from one side while reducing the injection of carriers on the other side.

A second technique involves doping type modulation. This can involve using a different type of carrier on the source side vs. the drain side. One example includes TFET (tunnel field effect transistor) devices. One such typical structure includes an n-type region near the source, a p-type channel, an n-type region at the edge of the channel near the drain, and a p-type carrier at the drain (as opposed to typically an n-type region near both the source and drain for a conventional FET). This operates with the mode of modulating of the p-n junction under the gate. Having an opposite type of carrier on the source vs. the drain also makes the device highly unidirectional.

A third technique involves Zener or Gunn or avalanche diodes created at the source or drain of a MOSFET. These diode types are introduced in the contact region just underneath the gate edge. These diodic structures enable a high level of unidirectionality due to their respective operations. However, placing the junction of the diode next to or under the gate ensures that an undesirable impact to the drive current is minimized.

The above techniques, can be improved further if the device is operated at low temperatures, although this is not a necessary criteria.

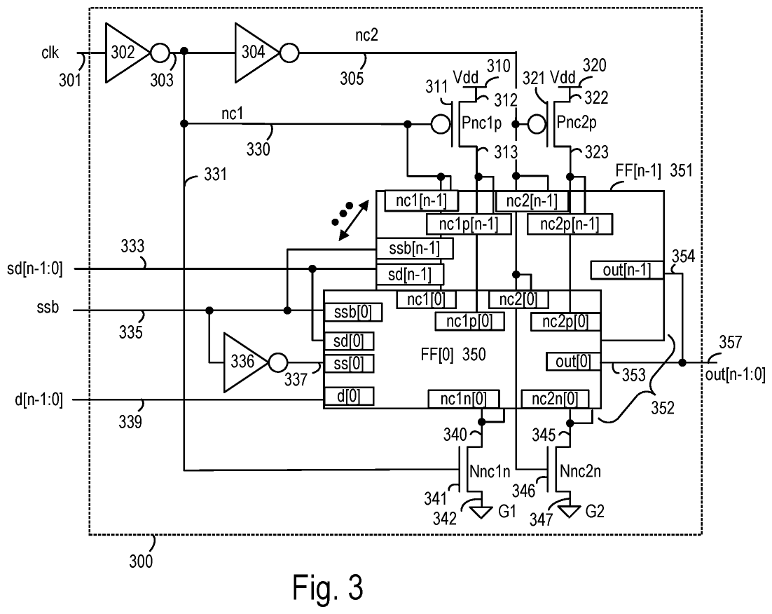

FIG. 3 depicts an example multi-bit flip-flop circuit 300 which uses unidirectional FETs, with tri-state keeper sharing, in accordance with various embodiments. To utilize the unidirectional attribute of the transistors, clock devices are shared across multiple flip-flops in a multi-bit standard cell. This sharing enables significant clock power reduction as well as reduced space requirements.

As in FIG. 1A, a set of n flip-flops 352 is provided, including FF[0] 350, . . . , FF[n−1] 351. The flip-flops include the input and output terminals of FIG. 1A. Also included are additional input terminals nc1p[0], . . . , nc1p[n−1] which are coupled to the drain terminal of a p-type FET Pnc1p, input terminals nc2p[0], . . . , nc2p[n−1] which are coupled to the drain terminal of a p-type FET Pnc2p, output terminals nc1n[0], . . . , nc1n[n−1] which are coupled to the drain terminal of an n-type FET Nnc1n, and output terminals nc2n[0], . . . , nc2n[n−1] which are coupled to the drain terminal of an n-type FET Nnc2n. Pnc1p, Pnc2p, Nnc1n and Nnc2n are shared or common devices/transistors which are coupled to each of the flip-flops in the multi-bit flip-flop circuit 300. They are shared among the different flip-flops.

The circuit receives a number of shared or common inputs including a clock signal (clk) on a path 301, a scan data signal sd[n−1:0] on a path 333, a scan select signal ssb on a path 335 and a data signal d[n−1:0] on a path 339.

Each flip-flop receives shared inputs at respective input terminals. For example, input terminals nc1[0], . . . , nc1[n−1] receive clk after it is inverted at an inverter 302 and provided on paths 303 and 330. Input terminals nc2[0], . . . , nc2[n−1] receive the signal on the path 303 after it is inverted at an inverter 304 and provided on a path 305. Input terminals nc1p[0], . . . , nc1p[n−1] are coupled to the drain terminal 313 of Pnc1p. A voltage at this drain terminal is a function of a voltage nc1 on the path 330 (which in turn is coupled to the control gate 311) and a power supply voltage Vdd at a power supply terminal 310, which is coupled to the source terminal 312. In particular, a voltage of the drain terminal 313 is high when nc1 is low. Input terminals nc2p[0], . . . , nc2p[n−1] are coupled to the drain terminal 323 of Pnc2p. A voltage at this drain terminal is a function of a voltage nc2 on the path 305 (which in turn is coupled to the control gate 321) and the power supply voltage Vdd at the power supply terminal 320, which is coupled to the source terminal 322. In particular, a voltage of the drain terminal 323 is high when nc2 is low. Nd1 and low are complementary so that one is high when the other is low.

Additionally, output terminals nc1n[0], . . . , nc1n[n−1] are coupled to the drain terminal 340 of Nnc1n. The signal nc1 on the paths 303 and 331 is coupled to the control gate 341 of this transistor. Terminals nc2n[0], . . . , nc2n[n−1] are coupled to the drain terminal 345 of Nnc2n. The signal nc2 on the path 305 is coupled to the control gate 346 of this transistor. The source 342 of Nnc1n is coupled to ground G1, and the source 347 of Nnc2n is coupled to ground G2.

Input terminals ssb[0], . . . ssb[n−1] receive ssb. Input terminals sd[0], . . . sd[n−1] receive a respective bit from the set of n bits denoted by sd[n−1:0]. Input terminals ss[0], . . . ss[n−1] receive a signal ss, which is the complement or inverse of ssb, after ssb is inverted at an inverter 336 and output on a path 337. Input terminals d[0], . . . d[n−1] receive a respective bit from the set of n data bits denoted by d[n−1:0]. Note that the d and ss input terminals are depicted here for FF[0] only for clarity. Each flip-flop may have the same input and output terminals, in one approach. Each flip-flop includes internal components which are controlled by the input signals to provide an output at a respective output terminal out[0], . . . , out[n−1] on paths 353, . . . , 354. The bits on the paths 353, . . . , 354 are combined at a path 357 to provide the final, multi-bit output out[n−1:0].

The inverters 302 and 304 and Pnc1p, Pnc2p, Nnc in and Nnc2n are clock devices in this example.

In some embodiments, the shared transistors are part of keeper circuits which maintain the data in storage nodes of the flip-flops. The keepers can be provided as reverse tri-state keepers and the clock devices are shared, in one possible approach. As mentioned, this approach can significantly reduce the clock transistor gate capacitance (excluding the local clock inverters).

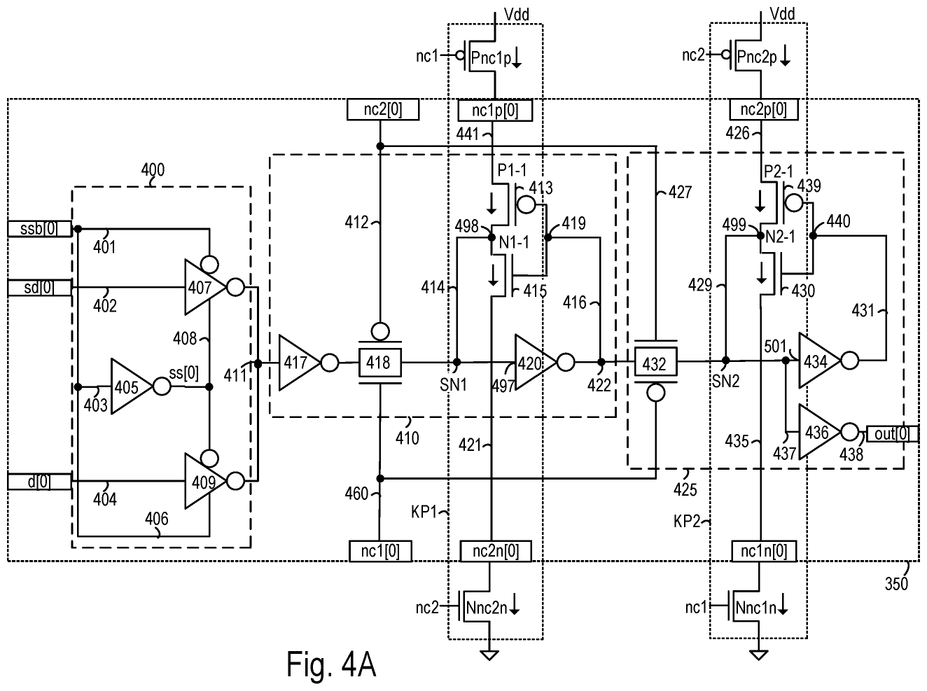

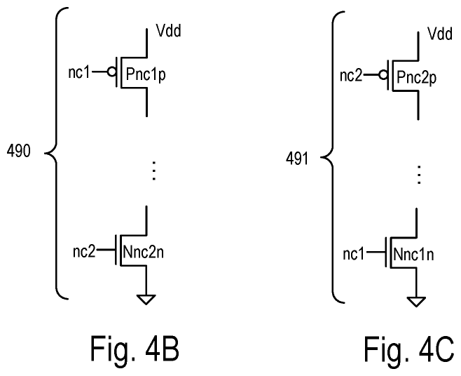

FIG. 4A depicts an example implementation of the flip-flop 350 of FIG. 3, with tri-state keeper sharing, in accordance with various embodiments. The flip-flop includes a serial arrangement of a multiplexer 400, a primary latch 410 and a secondary latch 425. The primary and secondary latches may also be referred to as first and second latches, respectively, or primary and secondary latches, respectively. Each latch is to latch data in a respective storage node SN1 or SN2 before the data is output at the output terminal out[0].

The flip-flop includes a multiplexer 400 which passes sd[0] on path 402 or d[0] on path 404 to a node 408. The multiplexer includes an inverter 405 and tri-state inverters 407 and 409. The tri-state invertor 407 can pass sd[0] based on ss[0] on node 408 and ssb[0] on path 401. ss[0] is output by the invertor 405 based on the input of ssb[0] on an input path 403. The tri-state invertor 409 can pass d[0] based on ssb[0] on path 406 and ss[0] on node 408. In a data latching mode of the flip-flop, the tri-state inverter 409 inverts and passes d[0] on path 404 to the node 411.

In the primary latch, the data bit is inverted at the inverter 417 and provided to the transmission gate 418. An inverting side of the transmission gate is coupled to the nc2[0] terminal via path 412 and an opposite non-inverting side of the transmission gate is coupled to the nc1[0] terminal via path 460. When the transmission gate 418 is conductive, e.g., the signal at nc2[0] is low and the signal at nc1[0] is high, the inverted data bit is passed to SN1.

A first keeper circuit KP1 (or first circuit, generally) helps maintain the data at SN1. The keeper circuit includes a series-connected p-type transistor P1-1 and n-type transistor N1-1. P1-1 is coupled to and in series with Pnc1p via path 441 and terminal nc1p[0]. N1-1 is coupled to and in series with Nnc2n via path 421 and output terminal nc2n[0]. In the keeper operation, the data bit at SN1 is provided to the input 497 of the inverter 420. The inverted value is output at the node 422, path 416 and node 419 which is coupled to the control gates 413 and 415 of P1-1 and N1-1, respectively. A node 498 represents an output from the pair of transistors. This output is provided via a path 414 back to SN1 to reinforce the voltage at SN1. The keeper reinforcement for KP1 occurs when Pnc1p and Nnc2n are in a conductive state, e.g., when nc1 is low and nc2 is high.

The downward pointing arrows associated with P1-1, N1-1, P2-1 and N2-1 indicate they are unidirectional devices which are configured to flow current in the direction from a high voltage to a lower voltage such as ground. The shared transistors Pnc1p, Pnc2p, Nnc2n and Nnc1n may bidirectional or unidirectional.

In the secondary latch, the data bit at the node 422 is passed by the transmission gate 432 to SN2 when the transmission gate 432 is enabled, e.g., when the signal at nc2[0] is high and the signal at nc1[0] is low. An inverting side of the transmission gate is coupled to the nc1[0] terminal via path 460 and an opposite non-inverting side of the transmission gate is coupled to the nc2[0] terminal via path 427. A second keeper circuit KP2 (or second circuit, generally) helps maintain the data at SN2. The keeper circuit includes a series-connected p-type transistor P2-1 and n-type transistor N2-1. P2-1 is coupled to and in series with Pnc2p via path 426 and terminal nc2p[0]. N2-1 is coupled to and in series with Nnc1n via path 435 and output terminal nc1n[0]. In the keeper operation, the data bit at SN2 is provided to the input 501 of the inverter 434. The inverted value is output at the path 431 and node 440 which is coupled to the control gates 439 and 430 of P2-1 and N2-1, respectively. A node 499 represents an output from the pair of transistors. This output is provided via a path 429 back to SN2 to reinforce the voltage at SN2. The keeper reinforcement for KP2 occurs when Pnc2p and Nnc1n are in a conductive state, e.g., when nc2 is low and nc1 is high.

The data at the storage node SN2 can be output via a path 437 and inverter 436 to a path 438 and the output terminal out[0].

Accordingly, each of the keeper circuits KP1 and KP2 is made up of transistors (e.g. internal transistors or other devices) within each individual flip-flop along with shared transistors (e.g. external transistors or other devices) external to the flip-flop. Generally, a keeper circuit can be made up of one or more internal transistors or other devices within each individual flip-flop and one or more shared transistors or other devices external to the flip-flop. Note that the shared external transistors are shown here for ease of understanding.

The transmission gates 418 and 432 are clock devices in this example.

Each flip-flop in the multi-bit flip-flop circuit may have the same configuration, in one approach.

P1-1, N1-1, P2-1 and N2-1 are examples of internal keeper devices (or internal devices, generally) and Pnc1p, Pnc2p, Nnc2n and Nnc1n are examples of shared keeper devices (or shared devices, generally).

FIG. 4B depicts an example first subset 490 of shared keeper devices consistent with FIG. 4A, in accordance with various embodiments. The first subset includes the transistors Pnc1p, which receives the clock signal nc1 at its control gate and Nnc2n, which receives the clock signal nc2 (the complement of nc1) at its control gate. The first subset is associated with the primary latch in one approach. The first subset may represent devices that are shared by the primary latch in each flip-flop of the multi-bit flip-flop circuit, for example.

FIG. 4C depicts an example second subset 491 of shared keeper devices consistent with FIG. 4A, in accordance with various embodiments. The second subset includes the transistors Pnc2p, which receives the clock signal nc2 at its control gate and Nnc1n, which receives the clock signal nc1 at its control gate. The second subset is associated with the secondary latch in one approach. The second subset may represent devices that are shared by the secondary latch in each flip-flop of the multi-bit flip-flop circuit, for example.

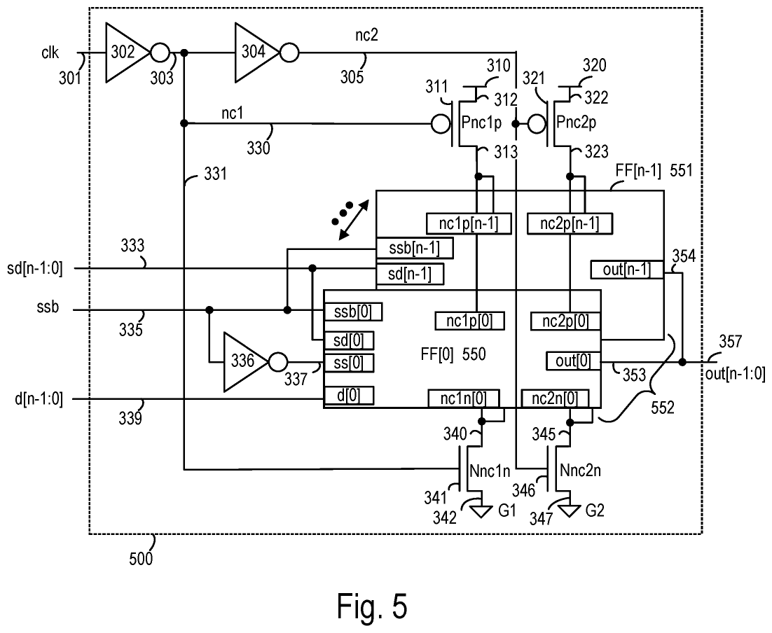

FIG. 5 depicts an example multi-bit flip-flop circuit 500 which uses unidirectional FETs, with tri-state keeper and/or pass gate sharing, in accordance with various embodiments. The circuit is similar to that of FIG. 3 except that input terminals for nc1 and nc2 are not used.

As in FIG. 3, a set of n flip-flops 552 is provided, including FF[0] 550, . . . , FF[n−1] 551. The flip-flops include the input and output terminals of FIG. 3 except for nc1[0], . . . , nc1[n−1] and nc2[0], . . . , nc2[n−1]. As before, input terminals nc1p[0], . . . , nc1p[n−1] are coupled to the drain terminal 313 of Pnc1p, input terminals nc2p[0], . . . , nc2p[n−1] are coupled to the drain terminal 323 of Pnc2p, output terminals nc1n[0], . . . , nc1n[n−1] are coupled to the drain terminal 340 of Nnc1n, and output terminals nc2n[0], . . . , nc2n[n−1] are coupled to the drain terminal 345 of Nnc2n.

The circuit 500 receives a number of shared or common inputs including a clock signal (clk) on a path 301, a scan data signal sd[n−1:0] on a path 333, a scan select signal ssb on a path 335 and a data signal d[n−1:0] on a path 339.

Each flip-flop receives shared inputs at respective input terminals. For example, input terminals nc1[0], . . . , nc1[n−1] receive clk after it is inverted at an inverter 302 and provided on paths 303 and 330. Input terminals nc2[0], . . . , nc2[n−1] receive the signal on the path 303 after it is inverted at an inverter 304 and provided on a path 305. Input terminals nc1p[0], . . . , nc1p[n−1] are coupled to the drain terminal 313 of Pnc1p. Input terminals nc2p[0], . . . , nc2p[n−1] are coupled to the drain terminal 313 of Pnc2p.

Additionally, output terminals nc1n[0], . . . , nc1n[n−1] are coupled to the drain terminal 340 of Nnc1n, and output terminals nc2n[0], . . . , nc2n[n−1] are coupled to the drain terminal 345 of Nnc2n.

The signals sd[n−1:0], ssb and d[n−1:0] are input as in FIG. 3.

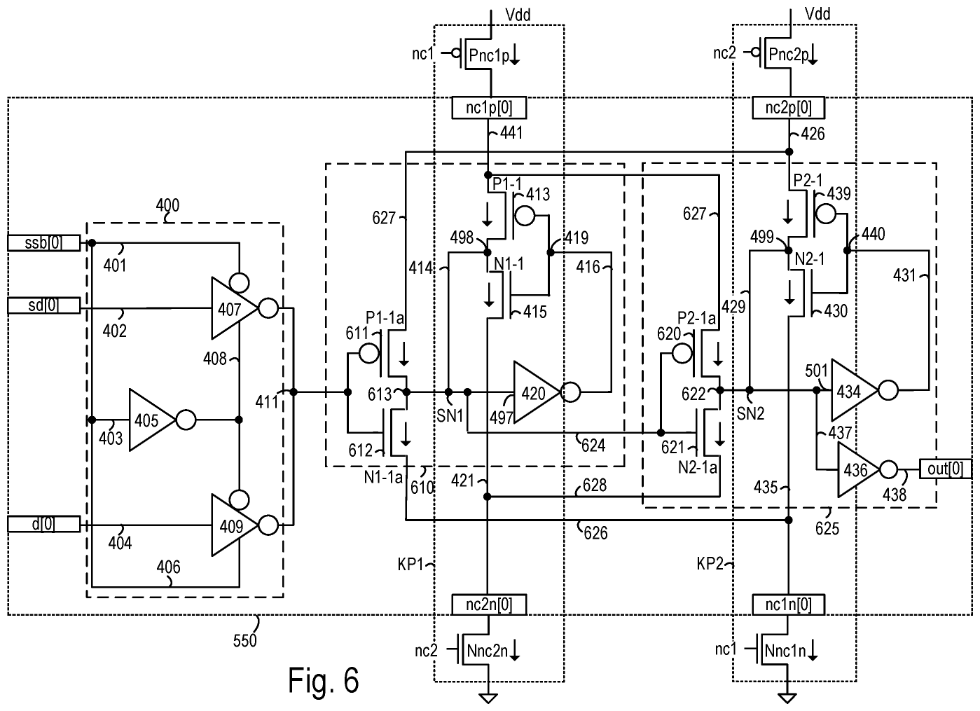

FIG. 6 depicts an example implementation of the flip-flop 550 of FIG. 5, with tri-state keeper and pass gate sharing, in accordance with various embodiments. In this case, the pass gates (transmission gates) 418 and 432 from FIG. 4A are converted to reverse tri-state inverters and the clock devices are shared. To maintain the same drive strength for worst case switching, the shared clock may not be downsized, in one approach. However, elimination of any clock width for the keeper devices can be achieved. This topology reduces the clock transistor gate capacitance by an additional significant amount (e.g., 11% in tests) compared to FIG. 4A.

The flip-flop includes a serial arrangement of the multiplexer 400, a primary latch 610 and a secondary latch 625. Each latch is to latch data in a respective storage node SN1 or SN2 before the data is output at the output terminal out[0].

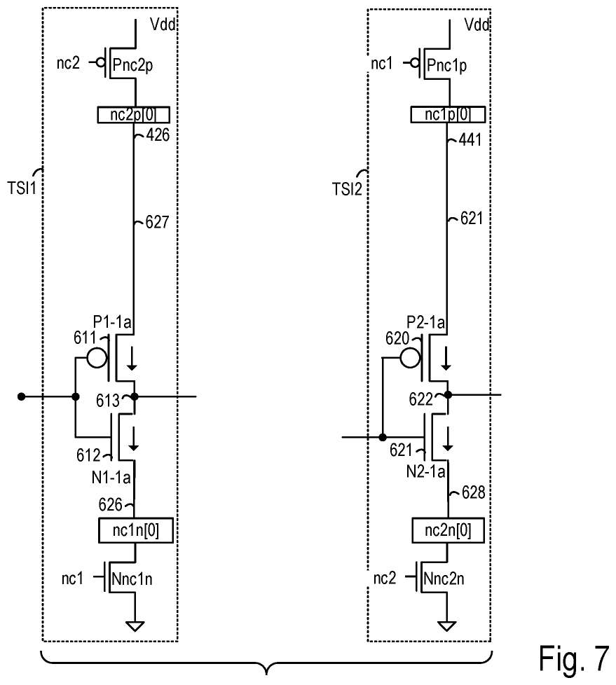

The multiplexer 400 passes d[0], for instance, to a node 411 which is coupled to control gates 611 and 612 of a p-type transistor P1-1a and an n-type transistor N1-1a, respectively, which are coupled in series with one another. P1-1a is coupled to and in series with Pnc2p via paths 627 and 426 and terminal nc2p[0]. N1-1a is coupled to and in series with Nnc1n via path 626 and output terminal nc1n[0]. See also FIG. 7.

A node 613 at the drain terminals of these transistors provides an output signal/voltage to SN1. As before, the first keeper circuit KP1 helps maintain the data at SN1. The keeper circuit includes a series-connected p-type transistor P1-1 and n-type transistor N1-1. P1-1 is coupled to and in series with Pnc1p via path 441 and terminal nc1p[0]. N1-1 is coupled to and in series with Nnc2n via path 421 and output terminal nc2n[0]. In the keeper operation, the data bit at SN1 is provided to the input 497 of the inverter 420. The inverted value is output at the path 416 and node 419 which is coupled to the control gates 413 and 415 of P1-1 and N1-1, respectively. The node 498 represents the output from the pair of transistors. This output is provided via the path 414 back to SN1 to reinforce the voltage at SN1. In one approach, each of the transistors denoted by a downward pointing arrow is unidirectional. As before, the shared transistors Pnc1p, Pnc2p, Nnc2n and Nnc1n may be bidirectional or unidirectional.

In the secondary latch, the data bit at SN1 is passed on a path 624 to the secondary latch. Path 624 is coupled to control gates 620 and 621 of a p-type transistor P2-1a and an n-type transistor N2-1a, which are coupled to one another in series. P2-1a is coupled to and in series with Pnc1p via paths 627 and 441 and terminal nc1p[0]. N2-1a is coupled to and in series with Nnc2n via path 628 and output terminal nc2n[0]. See also FIG. 7. A node 622 represents an output from the pair of transistors. This output is provided to SN2.

The second keeper circuit KP2 helps maintain the data at SN2. The keeper circuit includes the series-connected p-type transistor P2-1 and n-type transistor N2-1. P2-1 is coupled to and in series with Pnc2p via path 426 and terminal nc2p[0]. N2-1 is coupled to and in series with Nnc1n via path 435 and output terminal nc1n[0]. In the keeper operation, the data bit at SN2 is provided to the input 501 of the inverter 434. The inverted value is output at the path 431 and node 440 which is coupled to the control gates 439 and 430 of P2-1 and N2-1, respectively. The node 499 represents the output from the pair of transistors. This output is provided via a path 429 back to SN2 to reinforce the voltage at SN2. The data at the storage node SN2 can be output via a path 437 and inverter 436 to a path 438 and the output terminal out[0].

The flip-flop does not include internal clock devices in this example. Instead, the clock devices are the shared transistors Pnc1p, Pnc2p, Nnc2n and Nnc1n which are shared across the set of flip-flops in the multi-bit flip-flop circuit. The control gates of the clock transistors are connected to nc1 or nc2.

Each flip-flop in the multi-bit flip-flop circuit may have the same configuration, in one approach.

P1-1, N1-1, P2-1 and N2-1 are examples of internal keeper devices and Pnc1p, Pnc2p, Nnc2n and Nnc1n are examples of shared keeper devices.

FIG. 7 depicts an example configuration of a first tri-state inverter (TSI1) and a second tri-state inverter (TSI2) of the flip-flop 550 of FIG. 6, in accordance with various embodiments. The TSI1 includes, connected in series, Pnc2p, P1-1a, N1-1a and Nnc1n. The TSI2 includes, connected in series, Pnc1p, P2-1a, N2-1a and Nnc2n. The flip-flop of FIG. 6 thus shares the external devices Pnc2p, Nnc1n, Pnc1p and Nnc2n in two ways. First, they are shared to provide keepers in the primary and secondary latches. Second, they are shared to provide tri-state inverters in the primary and secondary latches. It can also be said that Pnc2p and Nnc1n are shared to provide keepers and tri-state inverters in the primary latch, and Pnc1p and Nnc2n are shared to provide keepers and tri-state inverters in the secondary latch.

The output of a tri-state inverter is either an inversion of the input or a high impedance (open circuit). The tri-state inverter also acts as a delay or buffering component. TSI1 provides an output when Pnc2p and Nnc1n are in a conductive state, e.g., when nc2 is low and nc1 is high. TSI2 provides an output when Pnc1p and Nnc2n are in a conductive state, e.g., when nc1 is low and nc2 is high.

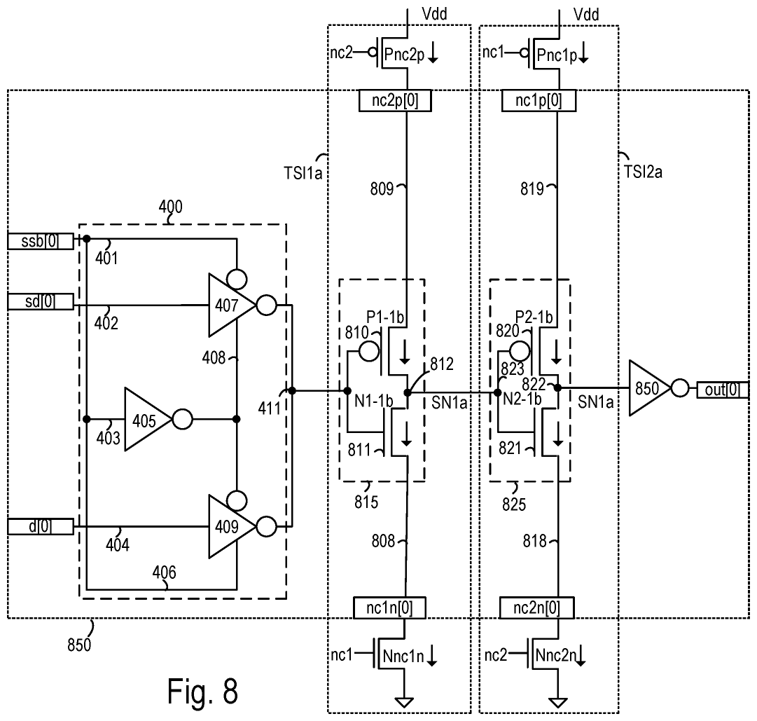

FIG. 8 depicts flip flop 850 as another example implementation of the flip flop 550 of FIG. 5, with pass gate sharing and no keeper, in accordance with various embodiments. This is an example of a keeperless flip-flop which may be suitable, e.g., for ultra-low-voltage and/or ultra-low temperature applications. In this case, additional data devices and keepers are eliminated for data power reduction and smaller area footprint.

In particular, in a first tri-state inverter TSI1a, the multiplexer 400 passes d[0], for instance, to the node 411 which is coupled to control gates 810 and 811 of a p-type transistor P1-1b and an n-type transistor N1-1b, respectively, which are coupled in series with one another. P1-1b is coupled to and in series with Pnc2p via path 809 and terminal nc2p[0]. N1-1b is coupled to and in series with Nnc1n via path 808 and output terminal nc1n[0]. A node 812 at the drain terminals of these transistors provides an output signal/voltage to a first sense node SN1a.

SN1a in turn is coupled to a node 823 in a second tri-state inverter TSI2a. The node 823 in turn is coupled to control gates 820 and 821 of a p-type transistor P2-1b and an n-type transistor N2-1b, respectively, which are coupled in series with one another. P1-1b is coupled to and in series with Pnc1p via path 819 and terminal nc1p[0]. N2-1b is coupled to and in series with Nnc2n via path 818 and output terminal nc2n[0]. A node 822 at the drain terminals of these transistors provides an output signal/voltage to a second sense node SN1b. The data at SN1a in turn is output via an inverter 850 to out[0].

In this example, the number of transistors in the flip-flop is advantageously minimized.

Varies alternative implementations are possible. For example, a p-type transistor may be shared for both the primary and secondary latches while an n-type transistor is not shared. In another example, an n-type transistor may be shared for both the primary and secondary latches while a p-type transistor is not shared. In another example, p-type and/or n-type transistors may be used shared for the primary latch but not the secondary latch, or for the secondary latch but not the primary latch. The shared and internal p-type transistors can be of the same type or of different types. The shared and internal n-type transistors can be of the same type or of different types. For example, different types of unidirectional transistors can be used. Moreover, the transistors can be FETs or other type of transistors. The transistor could also be replaced by other devices which provide a similar functionality.

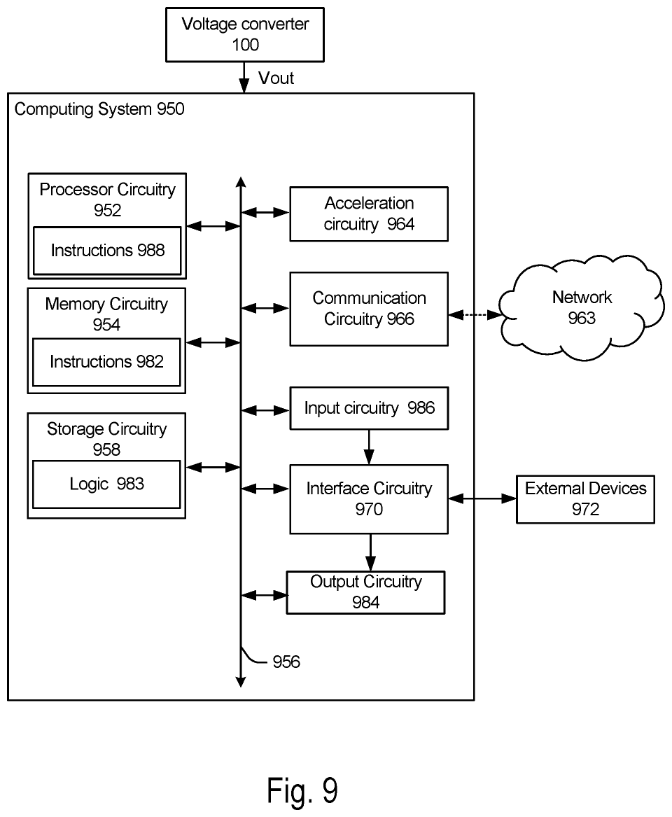

FIG. 9 illustrates an example of components that may be present in a computing system 950 for implementing the techniques (e.g., operations, processes, methods, and methodologies) described herein. The multi-bit flip-flop circuits such as those discussed in connection with FIGS. 3 to 8 can be provided in any of the circuitry of the computing system 950. For example, the multi-bit flip-flop circuits can be provided in at least one of

For one embodiment, at least one processor 952 may be packaged together with computational logic 982 and configured to practice aspects of various example embodiments described herein to form a System in Package (SiP), a System on Chip (SoC) or other circuit. The circuit can be part of a stacked tile/chiplet design which includes multiple integrated circuits/chips within the same package. The circuit can be considered to be an apparatus, a system or circuitry. The memory circuitry 954 may store instructions and the processor circuitry 952 may execute the instructions to perform the functions described herein.

The computing system 950 may include any combinations of the hardware or logical components referenced herein. The components may be implemented as ICs, portions thereof, discrete electronic devices, or other modules, instruction sets, programmable logic or algorithms, hardware, hardware accelerators, software, firmware, or a combination thereof adapted in the computing system 950, or as components otherwise incorporated within a chassis of a larger system. For one embodiment, at least one processor 952 may be packaged together with computational logic 982 and configured to practice aspects of various example embodiments described herein to form a System in Package (SiP) or a System on Chip (SoC).

The system 950 includes processor circuitry in the form of one or more processors 952. The processor circuitry 952 includes circuitry such as, but not limited to one or more processor cores and one or more of cache memory, low drop-out voltage regulators (LDOs), interrupt controllers, serial interfaces such as SPI, I2C or universal programmable serial interface circuit, real time clock (RTC), timer-counters including interval and watchdog timers, general purpose I/O, memory card controllers such as secure digital/multi-media card (SD/MMC) or similar, interfaces, mobile industry processor interface (MIPI) interfaces and Joint Test Access Group (JTAG) test access ports. In some implementations, the processor circuitry 952 may include one or more hardware accelerators (e.g., same or similar to acceleration circuitry 964), which may be microprocessors, programmable processing devices (e.g., FPGA, ASIC, etc.), or the like. The one or more accelerators may include, for example, computer vision and/or deep learning accelerators. In some implementations, the processor circuitry 952 may include on-chip memory circuitry, which may include any suitable volatile and/or non-volatile memory, such as DRAM, SRAM, EPROM, EEPROM, Flash memory, solid-state memory, and/or any other type of memory device technology, such as those discussed herein

The processor circuitry 952 may include, for example, one or more processor cores (CPUs), application processors, GPUs, RISC processors, Acorn RISC Machine (ARM) processors, CISC processors, one or more DSPs, one or more FPGAs, one or more PLDs, one or more ASICs, one or more baseband processors, one or more radio-frequency integrated circuits (RFIC), one or more microprocessors or controllers, a multi-core processor, a multithreaded processor, an ultra-low-voltage processor, an embedded processor, or any other known processing elements, or any suitable combination thereof. The processors (or cores) 952 may be coupled with or may include memory/storage and may be configured to execute instructions stored in the memory/storage to enable various applications or operating systems to run on the platform 950. The processors (or cores) 952 is configured to operate application software to provide a specific service to a user of the platform 950. In some embodiments, the processor(s) 952 may be a special-purpose processor(s)/controller(s) configured (or configurable) to operate according to the various embodiments herein.

As examples, the processor(s) 952 may include an Intel® Architecture Core™ based processor such as an i3, an i5, an i7, an i9 based processor; an Intel® microcontroller-based processor such as a Quark™, an Atom™, or other MCU-based processor; Pentium® processor(s), Xeon® processor(s), or another such processor available from Intel® Corporation, Santa Clara, California. However, any number other processors may be used, such as one or more of Advanced Micro Devices (AMD) Zen® Architecture such as Ryzen® or EPYC® processor(s), Accelerated Processing Units (APUs), MxGPUs, Epyc® processor(s), or the like; A5-A12 and/or S1-S4 processor(s) from Apple® Inc., Snapdragon™ or Centrig™ processor(s) from Qualcomm® Technologies, Inc., Texas Instruments, Inc.® Open Multimedia Applications Platform (OMAP)™ processor(s); a MIPS-based design from MIPS Technologies, Inc. such as MIPS Warrior M-class, Warrior I-class, and Warrior P-class processors; an ARM-based design licensed from ARM Holdings, Ltd., such as the ARM Cortex-A, Cortex-R, and Cortex-M family of processors; the ThunderX2® provided by Cavium™, Inc.; or the like. In some implementations, the processor(s) 952 may be a part of a system on a chip (SoC), System-in-Package (SiP), a multi-chip package (MCP), and/or the like, in which the processor(s) 952 and other components are formed into a single integrated circuit, or a single package, such as the Edison™ or Galileo™ SoC boards from Intel® Corporation. Other examples of the processor(s) 952 are mentioned elsewhere in the present disclosure.

The system 950 may include or be coupled to acceleration circuitry 964, which may be embodied by one or more AI/ML accelerators, a neural compute stick, neuromorphic hardware, an FPGA, an arrangement of GPUs, one or more SoCs (including programmable SoCs), one or more CPUs, one or more digital signal processors, dedicated ASICs (including programmable ASICs), PLDs such as complex (CPLDs) or high complexity PLDs (HCPLDs), and/or other forms of specialized processors or circuitry designed to accomplish one or more specialized tasks. These tasks may include AI/ML processing (e.g., including training, inferencing, and classification operations), visual data processing, network data processing, object detection, rule analysis, or the like. In FPGA-based implementations, the acceleration circuitry 964 may comprise logic blocks or logic fabric and other interconnected resources that may be programmed (configured) to perform various functions, such as the procedures, methods, functions, etc. of the various embodiments discussed herein. In such implementations, the acceleration circuitry 964 may also include memory cells (e.g., EPROM, EEPROM, flash memory, static memory (e.g., SRAM, anti-fuses, etc.) used to store logic blocks, logic fabric, data, etc. in LUTs and the like.

In some implementations, the processor circuitry 952 and/or acceleration circuitry 964 may include hardware elements specifically tailored for machine learning and/or artificial intelligence (AI) functionality. In these implementations, the processor circuitry 952 and/or acceleration circuitry 964 may be, or may include, an AI engine chip that can run many different kinds of AI instruction sets once loaded with the appropriate weightings and training code. Additionally or alternatively, the processor circuitry 952 and/or acceleration circuitry 964 may be, or may include, AI accelerator(s), which may be one or more of the aforementioned hardware accelerators designed for hardware acceleration of AI applications. As examples, these processor(s) or accelerators may be a cluster of artificial intelligence (AI) GPUs, tensor processing units (TPUs) developed by Google® Inc., Real AI Processors (RAPs™) provided by AlphaICs®, Nervana™ Neural Network Processors (NNPs) provided by Intel® Corp., Intel® Movidius™ Myriad™ X Vision Processing Unit (VPU), NVIDIA® PX™ based GPUs, the NM500 chip provided by General Vision®, Hardware 3 provided by Tesla®, Inc., an Epiphany™ based processor provided by Adapteva®, or the like. In some embodiments, the processor circuitry 952 and/or acceleration circuitry 964 and/or hardware accelerator circuitry may be implemented as AI accelerating co-processor(s), such as the Hexagon 685 DSP provided by Qualcomm®, the PowerVR 2NX Neural Net Accelerator (NNA) provided by Imagination Technologies Limited®, the Neural Engine core within the Apple® A11 or A12 Bionic SoC, the Neural Processing Unit (NPU) within the HiSilicon Kirin 970 provided by Huawei®, and/or the like. In some hardware-based implementations, individual subsystems of system 950 may be operated by the respective AI accelerating co-processor(s), AI GPUs, TPUs, or hardware accelerators (e.g., FPGAs, ASICs, DSPs, SoCs, etc.), etc., that are configured with appropriate logic blocks, bit stream(s), etc. to perform their respective functions.

The system 950 also includes system memory 954. Any number of memory devices may be used to provide for a given amount of system memory. As examples, the memory 954 may be, or include, volatile memory such as random access memory (RAM), static RAM (SRAM), dynamic RAM (DRAM), synchronous DRAM (SDRAM), RAMBUS® Dynamic Random Access Memory (RDRAM®), and/or any other desired type of volatile memory device. Additionally or alternatively, the memory 954 may be, or include, non-volatile memory such as read-only memory (ROM), erasable programmable ROM (EPROM), electrically erasable programmable (EEPROM), flash memory, non-volatile RAM, ferroelectric RAM, phase-change memory (PCM), flash memory, and/or any other desired type of non-volatile memory device. Access to the memory 954 is controlled by a memory controller. The individual memory devices may be of any number of different package types such as single die package (SDP), dual die package (DDP) or quad die package (Q17P). Any number of other memory implementations may be used, such as dual inline memory modules (DIMMs) of different varieties including but not limited to microDIMMs or MiniDIMMs.

Storage circuitry 958 provides persistent storage of information such as data, applications, operating systems and so forth. In an example, the storage 958 may be implemented via a solid-state disk drive (SSDD) and/or high-speed electrically erasable memory (commonly referred to as “flash memory”). Other devices that may be used for the storage 958 include flash memory cards, such as SD cards, microSD cards, XD picture cards, and the like, and USB flash drives. In an example, the memory device may be or may include memory devices that use chalcogenide glass, multi-threshold level NAND flash memory, NOR flash memory, single or multi-level Phase Change Memory (PCM), a resistive memory, nanowire memory, ferroelectric transistor random access memory (FeTRAM), anti-ferroelectric memory, magnetoresistive random access memory (MRAM) memory that incorporates memristor technology, phase change RAM (PRAM), resistive memory including the metal oxide base, the oxygen vacancy base and the conductive bridge Random Access Memory (CB-RAM), or spin transfer torque (STT)-MRAM, a spintronic magnetic junction memory based device, a magnetic tunneling junction (MTJ) based device, a Domain Wall (DW) and Spin Orbit Transfer (SOT) based device, a thyristor based memory device, a hard disk drive (HDD), micro HDD, of a combination thereof, and/or any other memory. The memory circuitry 954 and/or storage circuitry 958 may also incorporate three-dimensional (3D) cross-point (XPOINT) memories from Intel® and Micron®.

The memory circuitry 954 and/or storage circuitry 958 is/are configured to store computational logic 983 in the form of software, firmware, microcode, or hardware-level instructions to implement the techniques described herein. The computational logic 983 may be employed to store working copies and/or permanent copies of programming instructions, or data to create the programming instructions, for the operation of various components of system 950 (e.g., drivers, libraries, application programming interfaces (APIs), etc.), an operating system of system 950, one or more applications, and/or for carrying out the embodiments discussed herein. The computational logic 983 may be stored or loaded into memory circuitry 954 as instructions 982, or data to create the instructions 982, which are then accessed for execution by the processor circuitry 952 to carry out the functions described herein. The processor circuitry 952 and/or the acceleration circuitry 964 accesses the memory circuitry 954 and/or the storage circuitry 958 over the interconnect (IX) 956. The instructions 982 direct the processor circuitry 952 to perform a specific sequence or flow of actions, for example, as described with respect to flowchart(s) and block diagram(s) of operations and functionality depicted previously. The various elements may be implemented by assembler instructions supported by processor circuitry 952 or high-level languages that may be compiled into instructions 988, or data to create the instructions 988, to be executed by the processor circuitry 952. The permanent copy of the programming instructions may be placed into persistent storage devices of storage circuitry 958 in the factory or in the field through, for example, a distribution medium (not shown), through a communication interface (e.g., from a distribution server (not shown)), over-the-air (OTA), or any combination thereof.

The IX 956 couples the processor 952 to communication circuitry 966 for communications with other devices, such as a remote server (not shown) and the like. The communication circuitry 966 is a hardware element, or collection of hardware elements, used to communicate over one or more networks 963 and/or with other devices. In one example, communication circuitry 966 is, or includes, transceiver circuitry configured to enable wireless communications using any number of frequencies and protocols such as, for example, the Institute of Electrical and Electronics Engineers (IEEE) 802.11 (and/or variants thereof), IEEE 802.23.4, Bluetooth® and/or Bluetooth® low energy (BLE), ZigBee®, LoRaWAN™ (Long Range Wide Area Network), a cellular protocol such as 3GPP LTE and/or Fifth Generation (5G)/New Radio (NR), and/or the like. Additionally or alternatively, communication circuitry 966 is, or includes, one or more network interface controllers (NICs) to enable wired communication using, for example, an Ethernet connection, Controller Area Network (CAN), Local Interconnect Network (LIN), DeviceNet, ControlNet, Data Highway+, or PROFINET, among many others.

The IX 956 also couples the processor 952 to interface circuitry 970 that is used to connect system 950 with one or more external devices 972. The external devices 972 may include, for example, sensors, actuators, positioning circuitry (e.g., global navigation satellite system (GNSS)/Global Positioning System (GPS) circuitry), client devices, servers, network appliances (e.g., switches, hubs, routers, etc.), integrated photonics devices (e.g., optical neural network (ONN) integrated circuit (IC) and/or the like), and/or other like devices.

In some optional examples, various input/output (I/O) devices may be present within or connected to, the system 950, which are referred to as input circuitry 986 and output circuitry 984. The input circuitry 986 and output circuitry 984 include one or more user interfaces designed to enable user interaction with the platform 950 and/or peripheral component interfaces designed to enable peripheral component interaction with the platform 950. Input circuitry 986 may include any physical or virtual means for accepting an input including, inter alia, one or more physical or virtual buttons (e.g., a reset button), a physical keyboard, keypad, mouse, touchpad, touchscreen, microphones, scanner, headset, and/or the like. The output circuitry 984 may be included to show information or otherwise convey information, such as sensor readings, actuator position(s), or other like information. Data and/or graphics may be displayed on one or more user interface components of the output circuitry 984. Output circuitry 984 may include any number and/or combinations of audio or visual display, including, inter alia, one or more simple visual outputs/indicators (e.g., binary status indicators (e.g., light emitting diodes (LEDs)) and multi-character visual outputs, or more complex outputs such as display devices or touchscreens (e.g., Liquid Crystal Displays (LCD), LED displays, quantum dot displays, projectors, etc.), with the output of characters, graphics, multimedia objects, and the like being generated or produced from the operation of the platform 950. The output circuitry 984 may also include speakers and/or other audio emitting devices, printer(s), and/or the like. Additionally or alternatively, sensor(s) may be used as the input circuitry 984 (e.g., an image capture device, motion capture device, or the like) and one or more actuators may be used as the output device circuitry 984 (e.g., an actuator to provide haptic feedback or the like). Peripheral component interfaces may include, but are not limited to, a non-volatile memory port, a USB port, an audio jack, a power supply interface, etc. In some embodiments, a display or console hardware, in the context of the present system, may be used to provide output and receive input of an edge computing system; to manage components or services of an edge computing system; identify a state of an edge computing component or service; or to conduct any other number of management or administration functions or service use cases.

The components of the system 950 may communicate over the IX 956. The IX 956 may include any number of technologies, including ISA, extended ISA, I2C, SPI, point-to-point interfaces, power management bus (PMBus), PCI, PCIe, PCIx, Intel® UPI, Intel® Accelerator Link, Intel® CXL, CAPI, OpenCAPI, Intel® QPI, UPI, Intel® OPA IX, RapidIO™ system IXs, CCIX, Gen-Z Consortium IXs, a HyperTransport interconnect, NVLink provided by NVIDIA®, a Time-Trigger Protocol (TTP) system, a FlexRay system, PROFIBUS, and/or any number of other IX technologies. The IX 956 may be a proprietary bus, for example, used in a SoC based system.

The number, capability, and/or capacity of the elements of system 950 may vary, depending on whether computing system 950 is used as a stationary computing device (e.g., a server computer in a data center, a workstation, a desktop computer, etc.) or a mobile computing device (e.g., a smartphone, tablet computing device, laptop computer, game console, IoT device, etc.). In various implementations, the computing device system 950 may comprise one or more components of a data center, a desktop computer, a workstation, a laptop, a smartphone, a tablet, a digital camera, a smart appliance, a smart home hub, a network appliance, and/or any other device/system that processes data.

The techniques described herein can be performed partially or wholly by software or other instructions provided in a machine-readable storage medium (e.g., memory). The software is stored as processor-executable instructions (e.g., instructions to implement any other processes discussed herein). Instructions associated with the flowchart (and/or various embodiments) and executed to implement embodiments of the disclosed subject matter may be implemented as part of an operating system or a specific application, component, program, object, module, routine, or other sequence of instructions or organization of sequences of instructions.

The storage medium can be a tangible, non-transitory machine readable medium such as read only memory (ROM), random access memory (RAM), flash memory devices, floppy and other removable disks, magnetic storage media, optical storage media (e.g., Compact Disk Read-Only Memory (CD ROMS), Digital Versatile Disks (DVDs)), among others.

The storage medium may be included, e.g., in a communication device, a computing device, a network device, a personal digital assistant, a manufacturing tool, a mobile communication device, a cellular phone, a notebook computer, a tablet, a game console, a set top box, an embedded system, a TV (television), or a personal desktop computer.

Some non-limiting examples of various embodiments are presented below.

Example 1 includes an apparatus, comprising: a plurality of flip-flops, wherein each flip-flop of the plurality of flip-flops comprises internal devices and a storage node; and shared devices which are shared by the plurality of flip-flops, wherein for each flip-flop of the plurality of flip-flops, the internal devices are coupled to the shared devices and the internal devices combined with the shared devices are part of a circuit capable of maintaining a value in the storage node, wherein the internal devices comprise unidirectional transistors.

Example 2 include the apparatus of Example 1, wherein: in each flip-flop of the plurality of flip-flops, the internal devices comprise a p-type field-effect transistor (FET) in series with an n-type FET; and the shared devices comprise at least one of a p-type FET in series with the p-type FET of the internal devices or an n-type FET in series with the n-type FET of the internal devices.

Example 3 include the apparatus of Example 1 or 2, wherein: in each flip-flop of the plurality of flip-flops, the internal devices comprise a p-type field-effect transistor (FET) in series with an n-type FET; and the shared devices comprise a p-type FET in series with the p-type FET of the internal devices and an n-type FET in series with the n-type FET of the internal devices.

Example 4 include the apparatus of any one of Examples 1-3, wherein: each flip-flop of the plurality of flip-flops comprises a primary latch coupled to a secondary latch; and in each flip-flop of the plurality of flip-flops, the internal devices comprise internal devices in the primary latch and internal devices in the secondary latch, and the internal devices in the primary latch are coupled to a first subset of the shared devices and the internal devices in the secondary latch are coupled to a second subset of the shared devices.

Example 5 include the apparatus of Example 4, wherein: the first subset of the shared devices comprises a p-type field-effect transistor (FET) and an n-type FET; the second subset of the shared devices comprises a p-type FET and an n-type FET; and for each flip-flop of the plurality of flip-flops: the internal devices in the primary latch comprise series-connected p-type and n-type FETs in series with the p-type and n-type FETs of the first subset; and the internal devices in the secondary latch comprise series-connected p-type and n-type FETs in series with the p-type and n-type FETs of the second subset.

Example 6 include the apparatus of any one of Examples 1-5, wherein in each flip-flop of the plurality of flip-flops: the internal devices comprise a p-type field-effect transistor (FET) in series with an n-type FET; the storage node is coupled to drain terminals of the p-type and n-type FETs and to an input of an inverter; and an output of the inverter is coupled to control gates of the p-type and n-type FETs.

Example 7 include the apparatus of any one of Examples 1-6, wherein each flip-flop of the plurality of flip-flops comprises a transmission gate coupled to the storage node, and the transmission gate is to pass a data bit to the storage node based on complementary clock signals which the transmission gate is to receive.

Example 8 include the apparatus of any one of Examples 1-7, wherein for each flip-flop of the plurality of flip-flops, the internal devices combined with the shared devices comprise a tri-state inverter.

Example 9 include the apparatus of any one of Examples 1-8, further comprising at least one of an integrated circuit, a System on Chip, a System in Package, processor circuitry, memory circuitry, storage circuitry, acceleration circuitry, communication circuitry, input circuitry, interface circuitry, output circuitry, an external device or a computing device in which the plurality of flip-flops are provided.

Example 10 includes a flip-flop, comprising: a storage node; and a first p-type field-effect transistor (FET) in series with a first n-type FET, wherein: the storage node is coupled to drain terminals of the first p-type FET and the first n-type FET; the first p-type FET is in series with a shared p-type FET which is coupled to at least one other flip-flop; the first n-type FET is in series with a shared n-type FET which is coupled to the at least one other flip-flop; and the first p-type FET and the first n-type FET comprise unidirectional transistors.

Example 11 include the flip-flop of Example 10, wherein the first p-type FET and the first n-type FET combined with the shared p-type and n-type FETs are part of a circuit capable of maintaining a value in the storage node.

Example 12 include the flip-flop of Example 10, wherein the first p-type FET and the first n-type FET combined with the shared p-type and n-type FETs are part of a tri-state inverter.

Example 13 include the flip-flop of Example 12, wherein the tri-state inverter is to pass a data bit to the storage node based on complementary clock signals which the tri-state inverter is to receive.

Example 14 include the flip-flop of any one of Examples 10-13, further comprising a second p-type FET in series with a second n-type FET, wherein: the second p-type FET is in series with the shared p-type FET; the second n-type FET is in series with the shared n-type FET; the first p-type FET and the first n-type FET combined with the shared p-type and n-type FETs are part of a circuit capable of maintaining a value in the storage node; and the second p-type FET and the second n-type FET combined with the shared p-type and n-type FETs are part of a tri-state inverter.

Example 15 include the flip-flop of any one of Examples 10-14, wherein: a drain terminal of the shared p-type FET is coupled to a power supply; a source of the shared n-type FET is coupled to ground; and the unidirectional transistors are to flow current from the power supply to the ground.

Example 16 includes a flip-flop, comprising: a first storage node; a second storage node; and a first p-type field-effect transistor (FET) in series with a first n-type FET; and a second p-type FET in series with a second n-type FET, wherein: an output node between the first p-type FET and the first n-type FET is coupled to the first storage node; the first p-type FET is in series with a first shared p-type FET which is coupled to at least one other flip-flop and with a first shared n-type FET which is coupled to the at least one other flip-flop; an output node between the second p-type FET and the second n-type FET is coupled to the second storage node; and the second p-type FET is in series with a second shared p-type FET which is coupled to the at least one other flip-flop and with a second shared n-type FET which is coupled to the at least one other flip-flop.

Example 17 include the flip-flop of Example 16, wherein the first p-type FET, the first n-type FET, the second p-type FET and the second n-type FET are each unidirectional transistors.

Example 18 include the flip-flop of Example 16 or 17, wherein: the first p-type FET and the first n-type FET combined with the first shared p-type FET and the first shared n-type FET are part of a first tri-state inverter; and the second p-type FET and the second n-type FET combined with the second shared p-type FET and the second shared n-type FET are part of a second tri-state inverter.

Example 19 include the flip-flop of any one of Examples 16-18, wherein the flip-flop is keeperless.

Example 20 include the flip-flop of any one of Examples 16-19, wherein: the first storage node, the first p-type FET and the first n-type FET are in a primary latch; the second storage node, the second p-type FET and the second n-type FET are in a secondary latch; and the primary latch is coupled in series with the secondary latch without an inverter between the primary latch and the secondary latch.

Example 21 includes a method, comprising: receiving data bits at a plurality of flip-flops, wherein each flip-flop comprises a storage node to store a respective data bit; and reinforcing a value of the data bit at the storage node of each flip-flop with internal devices of the flip-flop and shared devices which are shared by the plurality of flip-flops, wherein the internal devices comprise unidirectional transistors.

Example 22 includes the method of Example 21, wherein the storage node is in a primary latch or a secondary latch of each flip-flop.

Example 23 includes the method of Example 21 or 22, wherein: in each flip-flop of the plurality of flip-flops, the internal devices comprise a p-type field-effect transistor (FET) in series with an n-type FET; and the shared devices comprise a p-type FET in series with the p-type FET of the internal devices and an n-type FET in series with the n-type FET of the internal devices.

Example 24 includes a non-transitory machine-readable storage including machine-readable instructions that, when executed, cause a processor or other circuit or computing device to implement the method of any one of Examples 21-23.

Example 25 includes a computer program comprising instructions which, when the program is executed by a computer, cause the computer to carry out the method of any one of Examples 21-23.

In the present detailed description, reference is made to the accompanying drawings that form a part hereof wherein like numerals designate like parts throughout, and in which is shown by way of illustration embodiments that may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

The terms “substantially,” “close,” “approximately,” “near,” and “about,” generally refer to being within +/−10% of a target value. Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For the purposes of the present disclosure, the phrases “A and/or B” and “A or B” mean (A), (B), or (A and B). For the purposes of the present disclosure, the phrase “A, B, and/or C” means (A), (B), (C), (A and B), (A and C), (B and C), or (A, B, and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

As used herein, the term “circuitry” may refer to, be part of, or include an Application Specific Integrated Circuit (ASIC), an electronic circuit, a processor (shared, dedicated, or group), a combinational logic circuit, and/or other suitable hardware components that provide the described functionality. As used herein, “computer-implemented method” may refer to any method executed by one or more processors, a computer system having one or more processors, a mobile device such as a smartphone (which may include one or more processors), a tablet, a laptop computer, a set-top box, a gaming console, and so forth.

The terms “coupled,” “communicatively coupled,” along with derivatives thereof are used herein. The term “coupled” may mean two or more elements are in direct physical or electrical contact with one another, may mean that two or more elements indirectly contact each other but still cooperate or interact with each other, and/or may mean that one or more other elements are coupled or connected between the elements that are said to be coupled with each other. The term “directly coupled” may mean that two or more elements are in direct contact with one another. The term “communicatively coupled” may mean that two or more elements may be in contact with one another by a means of communication including through a wire or other interconnect connection, through a wireless communication channel or link, and/or the like.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional elements.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

While the disclosure has been described in conjunction with specific embodiments thereof, many alternatives, modifications and variations of such embodiments will be apparent to those of ordinary skill in the art in light of the foregoing description. The embodiments of the disclosure are intended to embrace all such alternatives, modifications, and variations as to fall within the broad scope of the appended claims.

In addition, well-known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

What is claimed is:

1. An apparatus, comprising:
a plurality of flip-flops, wherein each flip-flop of the plurality of flip-flops comprises internal devices and a storage node; and
shared devices which are shared by the plurality of flip-flops, wherein for each flip-flop of the plurality of flip-flops, the internal devices are coupled to the shared devices and the internal devices combined with the shared devices are part of a circuit capable of maintaining a value in the storage node, wherein the internal devices comprise unidirectional transistors.

2. The apparatus of claim 1, wherein:
in each flip-flop of the plurality of flip-flops, the internal devices comprise a p-type field-effect transistor (FET) in series with an n-type FET; and
the shared devices comprise at least one of a p-type FET in series with the p-type FET of the internal devices or an n-type FET in series with the n-type FET of the internal devices.

3. The apparatus of claim 1, wherein:
in each flip-flop of the plurality of flip-flops, the internal devices comprise a p-type field-effect transistor (FET) in series with an n-type FET; and
the shared devices comprise a p-type FET in series with the p-type FET of the internal devices and an n-type FET in series with the n-type FET of the internal devices.

4. The apparatus of claim 1, wherein:
each flip-flop of the plurality of flip-flops comprises a primary latch coupled to a secondary latch; and
in each flip-flop of the plurality of flip-flops, the internal devices comprise internal devices in the primary latch and internal devices in the secondary latch, and the internal devices in the primary latch are coupled to a first subset of the shared devices and the internal devices in the secondary latch are coupled to a second subset of the shared devices.

5. The apparatus of claim 4, wherein:
the first subset of the shared devices comprises a p-type field-effect transistor (FET) and an n-type FET;
the second subset of the shared devices comprises a p-type FET and an n-type FET; and
for each flip-flop of the plurality of flip-flops:
the internal devices in the primary latch comprise series-connected p-type and n-type FETs in series with the p-type and n-type FETs of the first subset; and
the internal devices in the secondary latch comprise series-connected p-type and n-type FETs in series with the p-type and n-type FETs of the second subset.

6. The apparatus of claim 1, wherein in each flip-flop of the plurality of flip-flops:
the internal devices comprise a p-type field-effect transistor (FET) in series with an n-type FET;
the storage node is coupled to drain terminals of the p-type and n-type FETs and to an input of an inverter; and
an output of the inverter is coupled to control gates of the p-type and n-type FETs.

7. The apparatus of claim 1, wherein each flip-flop of the plurality of flip-flops comprises a transmission gate coupled to the storage node, and the transmission gate is to pass a data bit to the storage node based on complementary clock signals which the transmission gate is to receive.

8. The apparatus of claim 1, wherein for each flip-flop of the plurality of flip-flops, the internal devices combined with the shared devices comprise a tri-state inverter.

9. The apparatus of claim 1, further comprising at least one of an integrated circuit, a System on Chip, a System in Package, processor circuitry, memory circuitry, storage circuitry, acceleration circuitry, communication circuitry, input circuitry, interface circuitry, output circuitry, an external device or a computing device in which the plurality of flip-flops and the shared devices are provided.

10. A flip-flop, comprising:
a storage node; and
a first p-type field-effect transistor (FET) in series with a first n-type FET, wherein:
the storage node is coupled to drain terminals of the first p-type FET and the first n-type FET;
the first p-type FET is in series with a shared p-type FET which is coupled to at least one other flip-flop;
the first n-type FET is in series with a shared n-type FET which is coupled to the at least one other flip-flop; and
the first p-type FET and the first n-type FET comprise unidirectional transistors.

11. The flip-flop of claim 10, wherein the first p-type FET and the first n-type FET combined with the shared p-type and n-type FETs are part of a circuit capable of maintaining a value in the storage node.

12. The flip-flop of claim 10, wherein the first p-type FET and the first n-type FET combined with the shared p-type and n-type FETs are part of a tri-state inverter.

13. The flip-flop of claim 12, wherein the tri-state inverter is to pass a data bit to the storage node based on complementary clock signals which the tri-state inverter is to receive.

14. The flip-flop of claim 10, further comprising a second p-type FET in series with a second n-type FET, wherein:
the second p-type FET is in series with the shared p-type FET;
the second n-type FET is in series with the shared n-type FET;
the first p-type FET and the first n-type FET combined with the shared p-type and n-type FETs are part of a circuit capable of maintaining a value in the storage node; and
the second p-type FET and the second n-type FET combined with the shared p-type and n-type FETs are part of a tri-state inverter.

15. The flip-flop of claim 10, wherein:
a drain terminal of the shared p-type FET is coupled to a power supply;
a source of the shared n-type FET is coupled to ground; and
the unidirectional transistors are to flow current from the power supply to the ground.

16. A flip-flop, comprising:
a first storage node;
a second storage node; and
a first p-type field-effect transistor (FET) in series with a first n-type FET; and
a second p-type FET in series with a second n-type FET, wherein:
an output node between the first p-type FET and the first n-type FET is coupled to the first storage node;
the first p-type FET is in series with a first shared p-type FET which is coupled to at least one other flip-flop and with a first shared n-type FET which is coupled to the at least one other flip-flop;
an output node between the second p-type FET and the second n-type FET is coupled to the second storage node; and
the second p-type FET is in series with a second shared p-type FET which is coupled to the at least one other flip-flop and with a second shared n-type FET which is coupled to the at least one other flip-flop.

17. The flip-flop of claim 16, wherein the first p-type FET, the first n-type FET, the second p-type FET and the second n-type FET are each unidirectional transistors.

18. The flip-flop of claim 16, wherein:
the first p-type FET and the first n-type FET combined with the first shared p-type FET and the first shared n-type FET are part of a first tri-state inverter; and
the second p-type FET and the second n-type FET combined with the second shared p-type FET and the second shared n-type FET are part of a second tri-state inverter.

19. The flip-flop of claim 16, wherein the flip-flop is keeperless.

20. The flip-flop of claim 16, wherein:
the first storage node, the first p-type FET and the first n-type FET are in a primary latch;
the second storage node, the second p-type FET and the second n-type FET are in a secondary latch; and
the primary latch is coupled in series with the secondary latch without an inverter between the primary latch and the secondary latch.
